(19) United States
(12) Patent Application Publication
(10) Pub. No.: US 2010/0003833 A1
(43) Pub. Date: Jan. 7, 2010

(54) METHOD OF FORMING FLUORINE-CONTAINING DIELECTRIC FILM

(75) Inventors: Naoto Tsuji, Tama-shi (JP); Akinori Nakano, Tama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/166,052

(22) Filed: Jul. 1, 2008

(51) Int. Cl. H01L 21/314

(52) U.S. Cl. 438/769; 257/E21.266

(57) ABSTRACT

A method of forming a fluorine-containing dielectric film on a substrate by plasma CVD, includes: introducing as a process gas a fluorinated carbon compound having at least two double bonds in its molecule and an unsaturated hydrocarbon compound into a reaction space wherein a substrate is placed; and applying RF power to the reaction space to deposit a fluorine-containing dielectric film on the substrate by plasma CVD.

### BACKGROUND OF THE INVENTION

1. Field of the Invention

The present invention relates generally to a semiconductor technology, and specifically to a method of forming on a semiconductor substrate a carbon insulation film offering a low dielectric constant by using a plasma CVD (chemical vapor deposition) apparatus. In particular, the present invention relates to a method of forming such insulation film offering high thermal stability.

2. Description of the Related Art

In response to the recent demand for semiconductor devices offering higher speeds and finer structures, there is a need to reduce interconnection capacitance to prevent signal delays associated with multi-layer wiring technology.

To reduce interconnection capacitance, the dielectric constants of insulation films provided in a multi-layer wiring structure must be reduced, and this need has prompted the development of low-dielectric insulation films.

Conventional silicon oxide (SiOx) film is formed by adding an oxidization agent such as oxygen (O₂), nitrogen oxide (NO) or nitrous oxide (N₂O) to a silicon material gas such as SiH4, Si(OC₂H₅)₄, etc., and then applying heat or plasma energy, and the dielectric constant, or ε, of a SiOx film formed this way has been approx. 4.0. On the other hand, low-dielectric insulation films offering a dielectric constant ε of approx. 2.3 have been formed by the spin coat method using an inorganic silicon oxide glass (SOG) material.

Also, low-dielectric insulation films offering a dielectric constant ε of approx. 3.1 have been formed by plasma CVD using a silicon hydrocarbon (such as P-TMOS (phenyl trimethoxy silane)) as a material gas. Furthermore, low-dielectric insulation films offering a dielectric constant ε of approx. 2.5 have been formed by plasma CVD under optimized conditions using a silicon hydrocarbon containing multiple alkoxy groups as a material gas. In addition, low-dielectric fluorinated amorphous carbon films offering a dielectric constant ε of 2.0 to 2.4 have been formed by plasma CVD using CxFyHz as a material gas.

However, the aforementioned conventional approaches present the problems explained below.

First, an inorganic SOG insulation film achieved by the spin coat method presents such problems as the material not being distributed uniformly over a silicon substrate and the need for an expensive apparatus in the curing process following the application of the material.

If P-TMOS is used among silicon hydrocarbons, the polymerized oligomer cannot form a linear structure like the one offered by siloxane because P-TMOS has three alkoxy groups. As a result, a porous structure is not formed on a silicon substrate and the dielectric constant cannot be reduced to a desired level.

When a silicon hydrocarbon containing multiple alkoxy groups is used as a material gas, on the other hand, the polymerized oligomer obtained under optimized conditions forms a linear structure like the one offered by siloxane, and therefore a porous structure can be formed on a silicon substrate and the dielectric constant can be reduced to a desired level. However, such oligomer having a linear structure has a weak binding power between oligomers and thus the mechanical strength of the film becomes low.

Also, a conventional fluorinated amorphous carbon film formed by plasma CVD using CxFyHz as a material gas also presents a drawback in that the film has low heat resistance (370° C. or below).

### SUMMARY OF THE INVENTION

The present invention was developed in light of the problems explained above, and in an embodiment it is an object of the present invention to provide a method of forming a low-dielectric insulation film offering high thermal stability. In an embodiment it is another object of the present invention to provide a method of forming a low-dielectric insulation film with ease without increasing the apparatus cost.

In an aspect, the disclosed embodiments provide a method of forming a fluorine-containing dielectric film on a substrate by plasma CVD, comprising: (i) introducing as a process gas a fluorinated carbon compound having at least two double bonds in its molecule and an unsaturated hydrocarbon compound into a reaction space wherein a substrate is placed; and (ii) applying RF power to the reaction space to deposit a fluorine-containing dielectric film on the substrate by plasma CVD.

The above embodiment further includes, but is not limited to, the following embodiments:

In an embodiment, the RF power may be applied at less than 0.7 W/cm² (in an embodiment, 0.1-0.6 W/cm², preferably 0.2-0.4 W/cm²). In an embodiment, only high-frequency RF power may be applied. The high-frequency RF power may have a frequency of 2 MHz or higher, preferably 10 MHz or higher (or 20 MHz or higher).

In any of the foregoing embodiments, the step of applying the RF power may be conducted at a temperature of 300° C. or higher.

In any of the foregoing embodiments, the fluorinated carbon compound may be hexafluoro-1,3-butadiene or hexafluorocyclobutene.

In any of the foregoing embodiments, the unsaturated hydrocarbon compound may be selected from the group consisting of C₂H₄, C₃H₆, C₄H₈, C₅H₈, C₆H₁₀, C₂H₂, C₃H₄, and C₄H₆. In an embodiment, the unsaturated hydrocarbon compound may preferably be acetylene. In another embodiment, the unsaturated hydrocarbon compound may be cyclic and may have six or more carbon atoms.

In any of the foregoing embodiments, the step of introducing the process gas may further comprise introducing an inert gas. In an embodiment, the inert gas may be helium.

In any of the foregoing embodiment, at the step of introducing the process gas, a flow ratio of the fluorinated carbon compound to the unsaturated hydrocarbon compound may be 1/1 to 20/1 (in another embodiment, 2/1 to 10/1). In an embodiment, the inert gas may be introduced at a flow rate greater than that of the fluorinated carbon compound.

In any of the foregoing embodiments, the process gas may consist of the fluorinated carbon compound and the unsaturated hydrocarbon compound.

In any of the foregoing, the method may further comprise annealing the deposited film.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic cross sectional view of a plasma CVD apparatus usable in an embodiment of the present invention.

FIGS. 2A to 2E are graphs showing changes in growth rate, shrinkage, k-value, stress, and delta stress, respectively, when changing the density of high-frequency RF power in examples of the present invention.

FIGS. 3A to 3E are graphs showing changes in growth rate, shrinkage, k-value, stress, and delta stress, respectively, when changing the density of high-frequency RF power in comparative examples.

### DETAILED DESCRIPTION OF THE PREFERRED EMBODIMENT

The present invention will be explained in detail with reference to preferred embodiments for illustrative purposes, rather than limiting the present invention.

In the disclosed embodiments of the present invention, one or more of the problems in the conventional methods described above can be solved, and the disclosed embodiments may typically include the following:

A method of forming a low-dielectric insulation film by plasma CVD, comprising: a step to introduce, into a reaction chamber, a material gas constituted by a fluorinated hydrocarbon compound having at least one double bond, a process gas constituted by an inert gas, and depending on the condition, a material gas constituted by a hydrocarbon compound or hydrogen gas; a step to apply a first RF power and a second RF power by overlaying the two, or apply only a first RF power, in order to generate a plasma reaction field inside the reaction chamber; and a step to optimize the flow rate of each material gas and output of each RF power.

The fluorinated hydrocarbon compound having at least one double bond, being used as a material gas, is hexafluoro-1,3-butadiene (C₄F₆) in an embodiment. In other embodiment, hexafluorocyclobutene (C₄F₆) or the like can also be used, and two or more types of such gases may be mixed. The inert gas is He in an embodiment, but any gas selected from the group consisting of Kr, Xe, Ar, Ne and He can be used in other embodiment, and two or more types of such gases may be mixed. The hydrocarbon compound is C₂H₂ (acetylene) in an embodiment, but in other embodiment any compound selected from the group consisting of CH₄, C₂H₆, C₃H₈, C₂H₄ and C₂H₂ can be used, and two or more types of such gases may be mixed. By using a material fluorinated hydrocarbon compound having a double bond, cross-linking is promoted and a film offering high thermal stability can be formed. Furthermore, adding a hydrocarbon compound, particularly a hydrocarbon compound having a double bond, has the effect of improving the rate of film growth and also substantially reducing the shrinkage of film after annealing, suppressing the shrinkage of film to virtually zero.

For example, the rate of film shrinkage can be expressed by the formula below by assuming that annealing is performed for 1 hour in a N₂ atmosphere at 1 atm and 400° C.:

(Film thickness before annealing−Film thickness after annealing)/Film thickness before annealing×100 (%)

In an embodiment, the rate of shrinkage becomes 2% or less, or even 1% or less. In an embodiment, the film does not shrink all and its thickness even increases slightly. Under any condition, the rate of shrinkage is preferably ±3% or less, or more preferably ±2% or less. At these rates of shrinkage, thermal stability under stress is also favorable.

When a hydrocarbon compound is added, the dielectric constant tends to increase compared to when no hydrocarbon compound is added. However, the dielectric constant achieved by adding a hydrocarbon compound is generally 2.6 or less.

Also, these characteristics are dependent upon the power output from the RF power supply and if a high-frequency RF power supply is used, its power output can be adjusted to less than 0.7 W/cm² (or preferably to 0.6 W/cm² or below) in order to achieve favorable thermal stability under stress without raising the specific dielectric constant. When the power output from the RF power supply drops, the rate of film growth also drops. When a hydrocarbon compound is added, however, a high rate of film growth of approx. 300 nm/min (or in a range of 100 nm/min to 300 nm/min in an embodiment) can be achieved even when the power is less than 0.7 W/cm². The frequency used is high at 2 MHz or more, 10 MH or more, or 20 MHz or more (typically in a range of 10 to 30 MHz) in an embodiment, but such high-frequency power can be overlaid with the power output from a RF power supply of low frequency (less than 2 MHz) depending on the situation. Typically in this case, the power output from the low-frequency RF power supply is smaller than the power output from the high-frequency RF power supply.

Examples of film forming conditions are specified below.

Material fluorinated hydrocarbon compound having a double bond: 20 sccm to 1,000 sccm (preferably 50 sccm to 500 sccm)

Material hydrocarbon compound having a double bond: 5 sccm to 100 sccm (preferably 10 sccm to 50 sccm)

Inert gas: 50 sccm to 1,000 sccm (preferably 100 sccm to 800 sccm)

Film forming temperature: 250° C. to 500° C. (preferably 300° C. to 450° C.)

Film forming pressure: 50 Pa to 1,000 Pa (preferably 100 Pa to 800 Pa)

In the present disclosure where conditions and/or structures are not specified, the skilled artisan in the art can readily provide such conditions and/or structures, in view of the present disclosure, as a matter of routine experimentation.

The configuration of an apparatus that can be used to implement the present invention is explained below, along with the improvement effects by referring to examples of the present invention carried out using this apparatus.

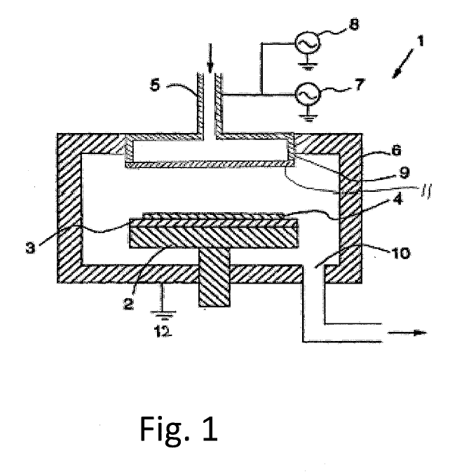

FIG. 1 shows an overview of a plasma processing apparatus that can be used under the present invention. The processing apparatus for implementing the present invention is not at all limited, and any favorable apparatus can be used, including any known apparatus. A plasma processing apparatus 1 has a reaction chamber 6, a gas introduction port 5, and a second electrode comprising a susceptor 3 and a heater 2. Gas is introduced through the gas introduction port 5 from a gas line (not illustrated). A first electrode 9 having a circular shape is positioned right below the gas introduction port 5, where this first electrode 9 has a hollow structure and has many small holes in the bottom face through which gas is injected toward a processing target 4. The first electrode 9 is also structured in such a way that a shower plate 11 having multiple gas introduction holes can be replaced to facilitate maintenance and also reduce the cost of parts.

Also, an exhaust port 10 is provided at the bottom of the reaction chamber 6. This exhaust port 10 is connected to an external vacuum pump (not illustrated), and the interior of the reaction chamber 6 is evacuated by means of this pump. The susceptor 3 is positioned in parallel with and facing the first electrode 9. The susceptor 3 retains the processing target 4 on top and heats the processing target 4 continuously using the heater 2 to maintain the substrate 4 at a specified temperature (0 to 500° C.). The gas introduction port 5 and first electrode 9 are insulated from the reaction chamber 6 and connected to a first high-frequency power supply 7 provided externally to the apparatus. A second high-frequency power supply 8 may also be connected. Numeral 12 indicates grounding. This way, the first electrode 9 and second electrode function as high-frequency electrodes to generate a plasma reaction field near the processing target 4. The type and quality of the film formed on the surface of the processing target 4 vary according to the type and flow rate of each material gas, temperature, type of RF frequency, as well as spatial distribution and potential distribution of plasma.

Annealing is typically performed for 1 hour in a N₂ atmosphere at 1 atm and 400° C. Take note that in addition to the aforementioned conditions, other equivalent conditions or known annealing conditions that can be implemented by those skilled in the art may be adopted. Annealing is not limited to thermal annealing, and UV annealing or a combination of thermal annealing and UV annealing may also be used. In the examples explained below, thermal stability was studied based on how the film characteristics changed before and after annealing.

In the following examples, the numerical numbers applied in embodiments can be modified by a range of at least ±50% in other embodiments, and the ranges applied in embodiments may include or exclude the endpoints.

### EXAMPLES

Specific examples of a method of forming a low-dielectric insulation film conforming to the present invention are explained below.

### (Experiment 1)

An experiment was conducted where the plasma CVD apparatus 1 shown in FIG. 1 was used to form an insulation film on a silicon substrate of Ø300 mm.

Conditions of Experiment

A: Material gas: (C₄F₆) (hexafluoro-1,3-butadiene) 130 sccm

B: He (helium) 200 sccm

C: C₂H₂ (acetylene) 25 sccm

First high-frequency power supply: 13.56 MHz, 0.15 to 0.9 W/cm²

Film forming temperature: 400° C.

Film forming pressure: 400 Pa

Annealing: 1 hour in a N₂ atmosphere at 1 atm and 400° C.

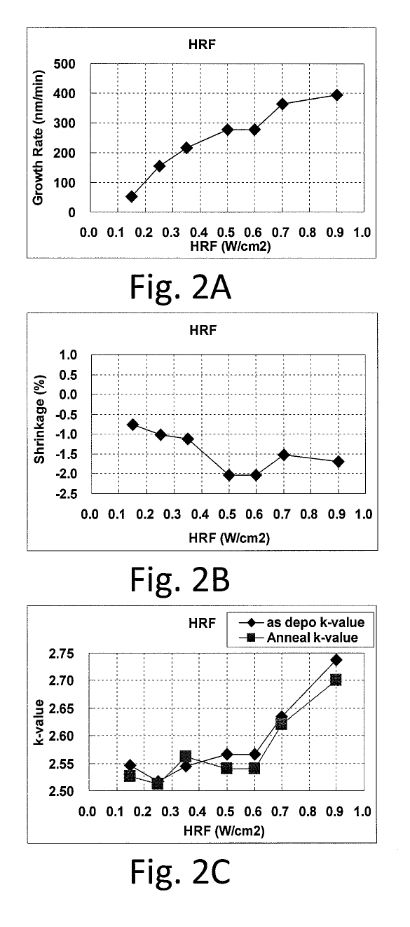

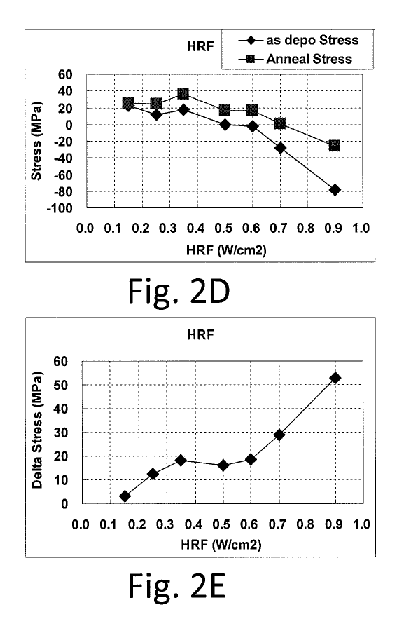

FIGS. 2A to 2C show the relationships of film characteristics before and after annealing on one hand, and film deposition pressure on the other, for a low-constant insulation film. FIGS. 2D and 2E show the residual stresses before and after annealing and the difference between the residual stress before annealing and residual stress after annealing.

When the power output from the RF power supply was less than 0.7 W/cm² (especially in a range of 0.2 to 0.6 W/cm²), the rate of film growth was high at around 100 to 300 nm/min. There was no shrinkage at all (the film increased slightly) as evident from the rates of film shrinkage of approx. −0.5% to −2.0%, the dielectric constant was approx. 2.6 or less (2.5 to 2.6), and the differential residual stress was less than 20 Mpa. In other words, the rate of film growth was high, there was no film shrinkage, and thermal stability was ensured. At the power levels of less than 0.4 W/cm², an excellent film offering an especially low rate of film shrinkage as well as high thermal stability and lower dielectric constant could be formed.

### (Comparative Experiment 1)

A dielectric film was formed in the same manner as in Experiment 1, except that acetylene was not added, under the following conditions:

Conditions of Experiment

A: Material gas: (C₄F₆) (hexafluoro-1,3-butadiene) 80 sccm

B: He (helium) 500 sccm

First high-frequency power supply: 13.56 MHz, 0.07 to 0.9 W/cm²

Film forming temperature: 400° C.

Film forming pressure: 300 Pa

Annealing: 1 hour in a N₂ atmosphere at 1 atm and 400° C.

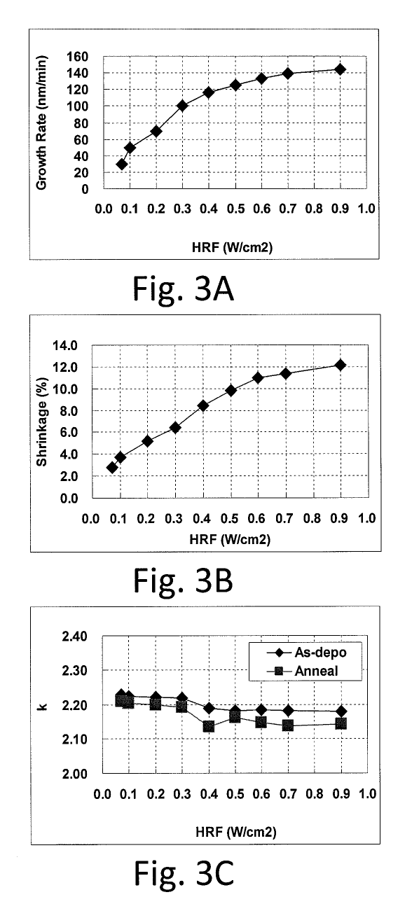

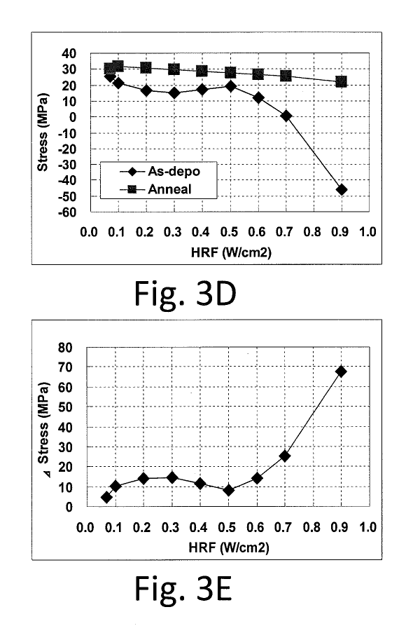

FIGS. 3A to 3C show the relationships of film characteristics before and after annealing for a low-constant insulation film. FIGS. 3D and 3E show the residual stresses before and after annealing and the difference between the residual stress before annealing and residual stress after annealing. The differential residual stress was less than 20 MPa in a range of less than 0.7 W/cm², indicating that thermal stability was ensured at these power levels. The specific dielectric constant was low at around 2.2, but the rate of film growth was low while the rate of film shrinkage was high. Compared to the rate of film shrinkage shown in FIG. 2B, it is clear that the film obtained in Experiment 1 has an astonishingly higher level of film stability compared to the film obtained in Comparative Experiment 1.

### EFFECTS OF THE INVENTION

As explained above, a method of forming a low-dielectric insulation film conforming to an embodiment of the present invention allows a low-dielectric insulation film offering high thermal stability to be formed. In an embodiment, a low-dielectric film offering an extremely low rate of film shrinkage as well as high thermal stability can be achieved by combining a fluorinated hydrocarbon compound having a double bond, hydrocarbon compound having a double bond, and inert gas, and accordingly a low-dielectric insulation film can be formed with ease without increasing the apparatus cost.

The present invention includes the above mentioned embodiments and other various embodiments including the following:

1) A method of forming a carbon insulation film on a substrate, comprising: a step to introduce into a reaction chamber in which a substrate heated to 300° C. or above is placed (A) a material gas constituted by a fluorinated hydrocarbon compound having at least one double bond, (B) a process gas constituted by an inert gas, and (C) a material gas constituted by a hydrocarbon compound or hydrogen gas; a step to apply RF power in order to generate a plasma reaction field inside the reaction chamber; and a step to deposit a film by controlling the flow rate of each reactant gas and intensity of the RF power, thereby forming an insulation film with a dielectric constant of 2.0 to 2.8.

2) A method according to 1) above, wherein the material gas constituted by a fluorinated hydrocarbon compound having at least one double bond is selected from the group consisting of hexafluoro-1,3-butadiene (C₄F₆) and hexafluorocyclobutene (C₄F₆).

3) A method according to 1) above, wherein the inert gas is selected from the group consisting of Kr, Xe, Ar, Ne and He.

4) A method according to 1) above, wherein the material gas constituted by a hydrocarbon compound is selected from the group consisting of CH₄, C₂H₆, C₃H₈, C₂H₄ and C₂H₂.

5) A method according to 1) above, wherein the RF power has a single frequency.

6) A method according to 5) above, wherein the frequency is 2 MHz or more.

7) A method according to 5) above, wherein the frequency is in a range of 10 to 30 MHz.

8) A method according to 5) above, wherein the intensity of the RF power is less than 0.7 W/cm².

It will be understood by those of skill in the art that numerous and various modifications can be made without departing from the spirit of the present invention. Therefore, it should be clearly understood that the forms of the present invention are illustrative only and are not intended to limit the scope of the present invention.

1. A method of forming a fluorine-containing dielectric film on a substrate by plasma CVD, comprising:
introducing as a process gas a fluorinated carbon compound having at least one double bond in its molecule and an unsaturated hydrocarbon compound into a reaction space wherein a substrate is placed; and
applying RF power to the reaction space to deposit a fluorine-containing dielectric film on the substrate by plasma CVD.

2. The method according to claim 1, wherein the RF power is applied at less than 0.7 W/cm².

3. The method according to claim 1, wherein the step of applying the RF power is conducted at a temperature of 300° C. or higher.

4. The method according to claim 1, wherein the fluorinated carbon compound is hexafluoro-1,3-butadiene or hexafluorocyclobutene.

5. The method according to claim 1, wherein the unsaturated hydrocarbon compound is acetylene.

6. The method according to claim 1, wherein the step of introducing the process gas further comprises introducing an inert gas.

7. The method according to claim 6, wherein the inert gas is helium.

8. The method according to claim 1, wherein at the step of introducing the process gas, a flow ratio of the fluorinated carbon compound to the unsaturated hydrocarbon compound is 1/1 to 20/1.

9. The method according to claim 6, wherein the inert gas is introduced at a flow rate greater than that of the fluorinated carbon compound.

10. The method according to claim 1, further comprising annealing the deposited film.

11. The method according to claim 1, wherein the process gas consists of the fluorinated carbon compound and the unsaturated hydrocarbon compound.
